(19) United States
(12) Patent Application Publication
(10) Pub. No.: US 2003/0042552 A1
(43) Pub. Date: Mar. 6, 2003

(54) Semiconductor device having metal silicide layer and method of manufacturing the same

(75) Inventor: Hee-Il Chae, Suwon-city (KR)

Correspondence Address: Steven M. Mills, MILLS & ONELLO LLP, Suite 605, Eleven Beacon Street, Boston, MA, 02108, US

(73) Assignee: Samsung Electronics Co., Ltd.

(21) Appl. No.: 10/217,927

(22) Filed: Aug. 13, 2002

(30) Foreign Application Priority Data
Sep. 3, 2001 (KR) 01-53837

(51) Int. Cl. H01L 29/76; H01L 29/94; H01L 31/062; H01L 31/113; H01L 31/119

(52) U.S. Cl. 257/384

(57) ABSTRACT

A semiconductor device having a metal suicide layer and a method of manufacturing the same are provided. A spacer material layer is formed on a semiconductor substrate on which a gate and a source and drain region having a low impurity concentration are formed. Only the spacer material layer, which is formed in a region in which a silicide layer is to be formed, is etched. A source and drain region having a high impurity concentration is formed in the exposed semiconductor substrate, and a silicide layer is formed on the source and drain region having a high impurity concentration. Since an extra silicide blocking layer (SBL) is not formed, a photomask process of patterning a SBL is not performed. That is, one photolithographic process is reduced in comparison with a conventional process of selectively forming a silicide layer. Thus, a process of manufacturing a semiconductor device can be simplified, thereby reducing process costs and reducing the danger of misalignment occurring during a photomask process.

### BACKGROUND OF THE INVENTION

1. Field of the Invention

The present invention relates to a semiconductor device having a metal silicide layer and a method of manufacturing the same, and more particularly, to a semiconductor device having a metal silicide layer, which is selectively formed without the formation of an extra silicide blocking layer (SBL), and a method of manufacturing the same.

2. Description of the Related Art

As semiconductor devices become highly integrated, the line widths of gate electrodes and source and drain regions decrease. Thus, the resistance of devices increases, and signal transmission time is delayed further. As a result, in order to lower the resistance of gate electrodes and reduce contact resistance with source and drain regions and metal interconnections, a silicide layer has recently been applied in gate electrodes and source and drain regions.

A silicide layer, which is an alloy of metal and silicon, is formed by thermal treatment after silicon and a metal having a high melting point are stacked. In particular, a process of forming a silicide layer is essential when manufacturing transistors used in logic devices.

In general, a silicide layer is not formed on all regions of a device but is selectively formed only on specific parts of a device. For example, in the case of a merged flash memory logic (MFL) process in which flash memory cells and logic devices are merged in one chip, a silicide layer is not formed in source and drain regions of the flash memory cells but is selectively formed only on gate electrodes of the flash memory cells and gate electrodes and source and drain regions of the logic devices. Further, in the case of a liquid crystal display (LCD) driver IC (LDI) as a driving device of a LCD, a silicide layer is selectively formed on only source and drain regions in a high-voltage MOS region and a low-voltage MOS region.

A process of selectively forming a silicide layer of a LDI will be described below.

FIGS. 1 through 7 are sectional views illustrating a process of selectively forming a silicide layer of a LDI according to prior art.

In FIG. 1, a high-voltage MOS region A and a low-voltage MOS region B are defined on a semiconductor substrate 100 on which a device isolation layer 110 is included, and a gate 120 is formed on the semiconductor substrate 100. The gate 120 is formed of a stack of polysilicon and tungsten silicide.

Source and drain regions 130, 140, 150, and 160, each having a low impurity concentration, are formed by implanting impurity ions having a low impurity concentration.

As shown in FIG. 1, the source and drain regions 130, 140, 150, and 160, each having a low impurity concentration, are formed deeper in the high-voltage MOS region A than the low-voltage MOS region B. In order to prevent a short channel effect due to the deeply-formed source and drain regions 130, 140, 150, and 160, each having a low impurity concentration, in the semiconductor substrate 100, the width of a gate in the high-voltage MOS region A is larger than the width of a gate in the low-voltage MOS region B.

In FIG. 2, a spacer material layer (not shown) is formed on the entire surface of the semiconductor substrate 100, the spacer material layer is etched by dry etching to form a spacer 170 on both sidewalls of the gate 120.

In FIG. 3, a first photoresist pattern 180, which exposes part of the source and drain region 130 having a low impurity concentration in a high-voltage NMOS region and a low-voltage NMOS region, is formed. N-type impurity ions having a high impurity concentration are implanted into the semiconductor substrate 100 exposed by the first photoresist pattern 180, thereby forming source and drain regions 190 and 200, each having a low impurity concentration, in the high-voltage NMOS region and the low-voltage NMOS region. As shown in FIG. 3, the source and drain regions in the high-voltage MOS region A are formed of a double diffused drain (DDD) structure in which the source and drain region 130 having a high impurity concentration surrounds the source and drain region 190 having a low impurity concentration, and the source and drain regions in the low-voltage MOS region B is formed of a lightly doped drain (LDD) structure.

The first photoresist pattern 180 is removed, and a second photoresist pattern 210 is formed as shown in FIG. 4. The second photoresist pattern 210 exposes part of the source and drain region 140 having a low impurity concentration in a high-voltage PMOS region and a low-voltage PMOS region. P-type impurity ions having a high impurity concentration are implanted into the semiconductor substrate 100 exposed by the second photoresist pattern 210, thereby forming a source and drain region 220 having a low impurity concentration in the high-voltage PMOS region and a source and drain region 230 having a high impurity concentration in the low-voltage PMOS region. Like the formation of the source and drain regions 190 and 200, each having a high impurity concentration, in the NMOS regions, the source and drain regions in the high-voltage MOS region A are formed of the double diffused drain (DDD) structure in which the source and drain region 140 having a low impurity concentration surrounds the source and drain region 220 having a high impurity concentration, and the source and drain regions in the low-voltage MOS region B is formed of the lightly doped drain (LDD) structure.

The second photoresist pattern 210 is removed, and a silicide blocking layer (SBL) 240 is formed on the entire surface of the semiconductor substrate 100, as shown in FIG. 5. The silicide blocking layer (SBL) 240 is formed of oxide or nitride. In FIG. 6, a third photoresist pattern 250 is formed on the SBL 240. The third photoresist pattern 250 is formed so as to expose the SBL 240 on the source and drain regions 190 and 220, each having a high impurity concentration, in the high-voltage MOS region A and the SBL 240 on the entire surface of the low-voltage MOS region B. That is, the third photoresist pattern 250 is a photoresist pattern for defining a region on which a silicide layer is selectively formed.

Although not shown, the SBL 240 exposed by the third photoresist pattern 250 is etched to expose the surface of the semiconductor substrate 100 on which a silicide layer is to be formed. Referring to FIG. 7, the third photoresist pattern 250 is removed, a silicide layer 260 is formed on the top surfaces of the source and drain regions 190 and 220, each having a high impurity concentration, in the high-voltage MOS region A and on the top surfaces of the source and drain regions 200 and 230, each having a high impurity concentration, in the low-voltage MOS region B.

As mentioned above, in order to selectively form a silicide layer in a semiconductor device, a SBL is formed, and an extra photoresist pattern (the third photoresist pattern) for patterning the SBL is formed. That is, a process of a SBL photomask is performed. Whenever one photoresist pattern is formed, a photomask process is added. By adding additional photomask processes, the process of manufacturing a semiconductor device becomes complicated, and thus, process costs increase.

The more photomask processes there are and the finer patterns are, the greater the possibility of misalignment occurring. That is, misalignment can occur during a photomask process of patterning a silicide layer, and patterns cannot be precisely formed in a region on which a silicide layer is formed.

### SUMMARY OF THE INVENTION

To solve the above problems, it is an objective of the present invention to provide a semiconductor device and a method of manufacturing the semiconductor device in which a silicide blocking layer (SBL) is not formed during a process of selectively forming a suicide layer, and thus the number of photomask processes can be reduced, thereby simplifying a process of manufacturing a semiconductor device.

According to one aspect of the present invention, there is provided a semiconductor device. The semiconductor device includes a semiconductor substrate on which a first region is defined, a gate, which is formed in the first region of the semiconductor substrate, a source and drain region having a high impurity concentration, which is formed apart from the gate in the semiconductor substrate at both sides of the gate, a source and drain region having a low impurity concentration, which is formed to surround the source and drain region having a high impurity concentration in the semiconductor substrate at both sides of the gate, a silicide layer, which is formed on the top surface of the source and drain region having a high impurity concentration, and a spacer layer, which is formed on the surface of the semiconductor substrate in the first region in which the gate is formed and exposes only the suicide layer.

The semiconductor substrate further includes a second region, a gate, which is formed in the second region of the semiconductor substrate, a spacer, which is formed on both sidewalls of the gate in the second region, a source and drain region having a low impurity concentration, which is formed under the spacer of the semiconductor substrate, a source and drain region having a high impurity concentration, which is formed outside of the spacer of the semiconductor substrate, and a silicide layer, which is formed on the top surface of the source and drain region having a high impurity concentration in the second region.

According to another aspect of the present invention, there is provided a method of manufacturing a semiconductor device. A semiconductor substrate, which includes a first region and a second region, is prepared. A gate is formed on the first and second regions of the semiconductor substrate. A source and drain region having a low impurity concentration at both sides of the gate is formed in the semiconductor substrate. A spacer material layer is formed on the surface of the semiconductor substrate on which the gate and the source and drain region having a low impurity concentration are formed. A spacer is formed on both sidewalls of the gate in the first region by etching the spacer material layer in the first region. A source and drain region having a high impurity concentration at both sides of the spacer is formed in the semiconductor substrate. A silicide layer is formed on the top surface of the source and drain region having a high impurity concentration.

In a case where the first region is a low-voltage MOS device, and the second region is a high-voltage MOS device, in the step of forming a spacer in the first region, a spacer material layer, which is formed on the top surface of part of the source and drain region having a low impurity concentration in the second region, is simultaneously etched, and part of the source and drain region having a low impurity concentration in the second region is exposed, and a source and drain region having a high impurity concentration is formed on the exposed part of the source and drain region having a low impurity concentration in the second region. A silicide layer is formed on the top surface of the source and drain region having a high impurity concentration.

According to another aspect of the present invention, there is provided a method of manufacturing a semiconductor device. A semiconductor substrate, which includes a high-voltage PMOS region, a high-voltage NMOS region, a low-voltage PMOS region, and a low-voltage NMOS region, is prepared. A gate and a source and drain region having a low impurity concentration are formed in each region of the semiconductor substrate. A spacer material layer is formed on the surface of the semiconductor substrate on which the gate and the source and drain region having a low impurity concentration are formed. A first photoresist pattern is formed on the semiconductor substrate on which the spacer material layer is formed. The spacer material layer, which is formed on the top surface of part of the source and drain region having a low impurity concentration in the high-voltage NMOS region, is etched by using the first photoresist pattern and simultaneously a spacer is formed on both sidewalls of the gate in the low-voltage NMOS region. The first photoresist pattern is removed, and a source and drain region having a high impurity concentration in the high-voltage NMOS region and a source and drain region having a high impurity concentration in the low-voltage NMOS region are formed. A second photoresist pattern is formed on the semiconductor substrate. The spacer material layer, which is formed on the top surface of part of the source and drain region having a low impurity concentration in the high-voltage PMOS region, is etched using the second photoresist pattern as a mask and simultaneously forming a spacer on both sidewalls of the gate in the low-voltage PMOS region. The second photoresist pattern is removed, and a source and drain region having a high impurity concentration in the high-voltage PMOS region and a source and drain region having a high impurity concentration in the low-voltage PMOS region are formed. A silicide layer is formed on the top surface of the source and drain region having a high impurity concentration in the high-voltage PMOS and NMOS regions and on the top surface of the source and drain region having a high impurity concentration in the low-voltage PMOS and NMOS regions.

The first photoresist pattern exposes the part of the source and drain region having a low impurity concentration in the high-voltage NMOS region and the low-voltage NMOS region, and the second photoresist pattern exposes the part of the source and drain region having a low impurity concentration in the high-voltage PMOS region and the low-voltage PMOS region.

### BRIEF DESCRIPTION OF THE DRAWINGS

The foregoing and other objects, features and advantages of the invention will be apparent from the more particular description of a preferred embodiment of the invention, as illustrated in the accompanying drawings in which like reference characters refer to the same parts throughout the different views. The drawings are not necessarily to scale, emphasis instead being placed upon illustrating the principles of the invention.

FIGS. 1 through 7 are sectional views illustrating a prior art process of manufacturing a semiconductor device having a silicide layer, which is selectively formed.

FIGS. 8 through 12 are sectional views illustrating a process of manufacturing a semiconductor device having a silicide layer, which is selectively formed, according to the present invention.

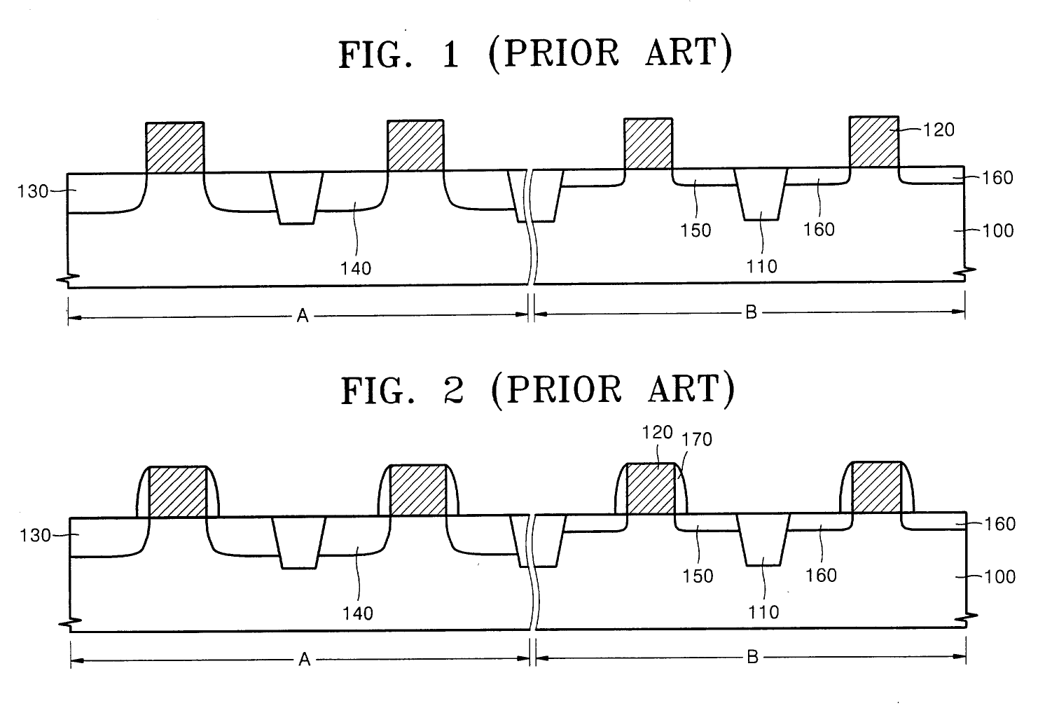

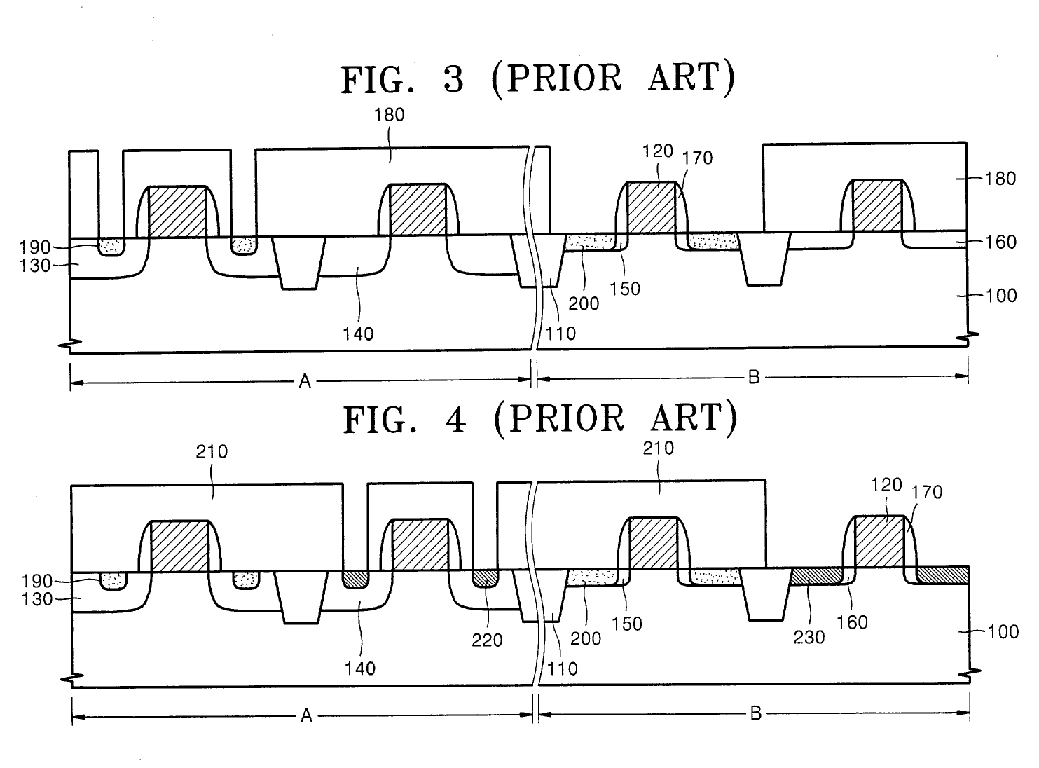

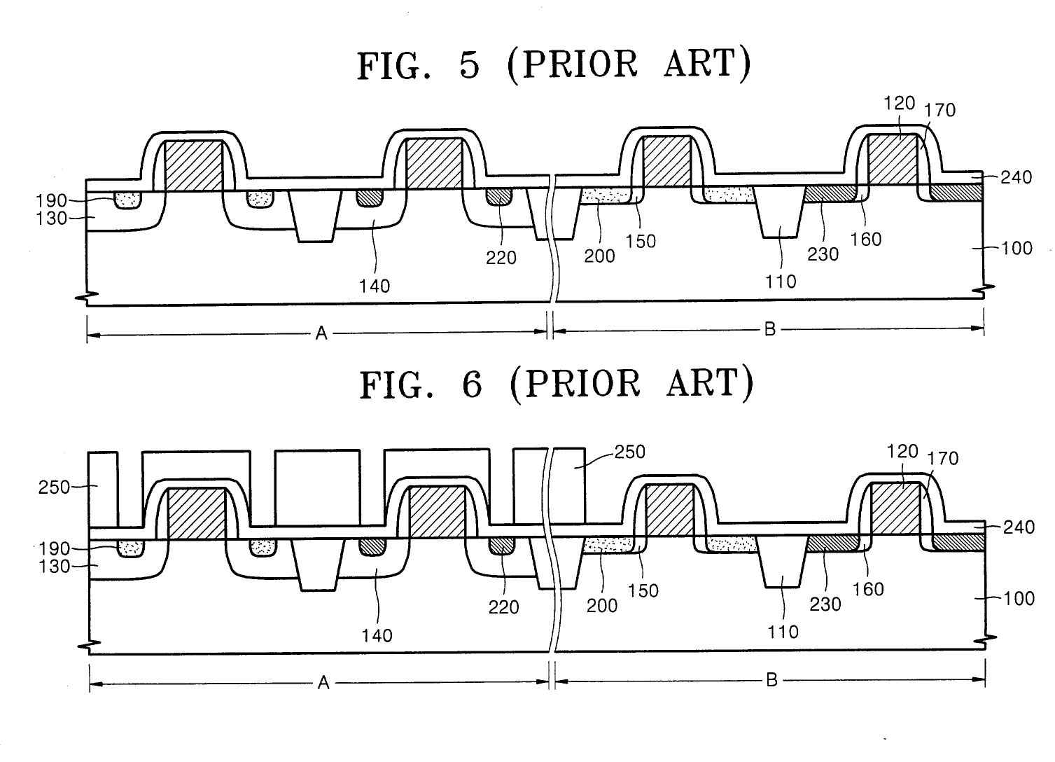

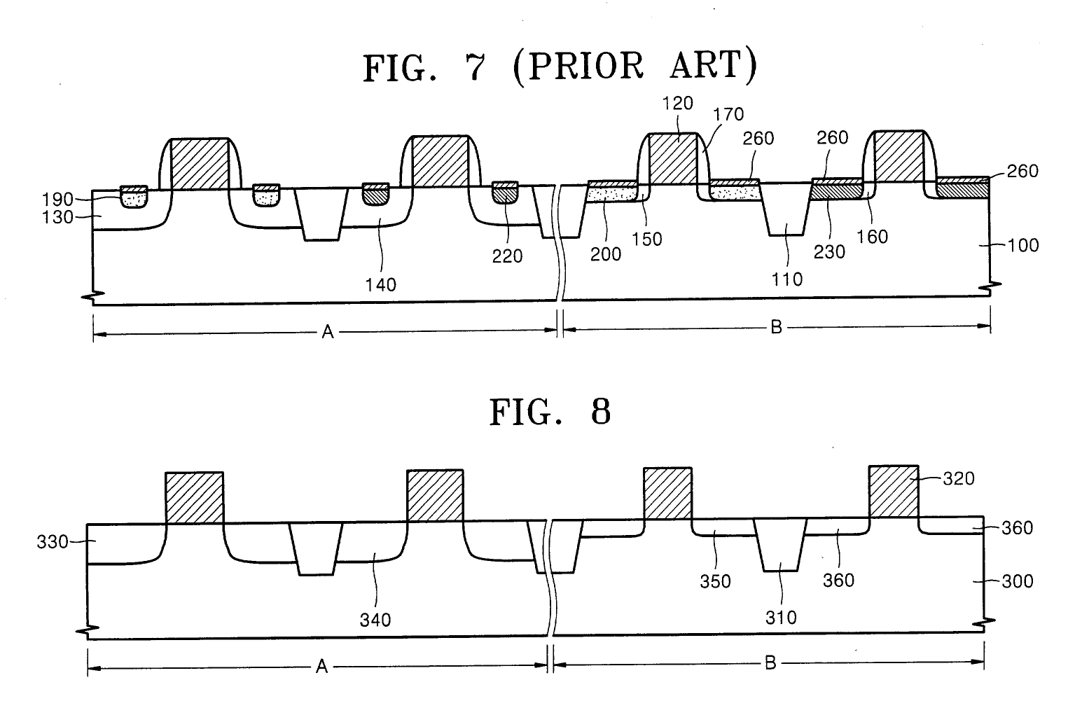

### DETAILED DESCRIPTION OF PREFERRED EMBODIMENTS OF THE INVENTION

In the following detailed description of the preferred embodiments, the invention is described in terms of an exemplary process of selectively forming a silicide layer on a liquid crystal display (LCD) driver IC (LDI) and a device formed by the process. It will be understood that the invention is applicable to a process of selectively forming a silicide layer on a semiconductor device and a device formed by the process.

In FIG. 8, a high-voltage MOS region A and a low-voltage MOS region B are defined in a semiconductor substrate 300 on which a device isolation layer 310 is formed, and a gate 320 is formed on the semiconductor substrate 300.

A high-voltage MOS transistor having a high threshold voltage is formed in peripheral circuits such as a sense amplifier and a modifier, and a low-voltage MOS transistor having a low threshold voltage is used in a cell memory device.

Next, impurity ions are implanted, and thus a source and drain region 330 having a low impurity concentration is formed in a high-voltage NMOS region, a source and drain region 340 having a low impurity concentration is formed in a high-voltage PMOS region, a source and drain region 350 having a low impurity concentration is formed in a low-voltage NMOS region, and a source and drain region 360 having a low impurity concentration is formed in a low-voltage PMOS region. Source and drain regions having a low impurity concentration and source and drain regions having a high impurity concentration are formed by adjusting the concentration of implanted impurity ions.

Source and drain regions having a high or low impurity concentration are formed by implanting ions such as P, As, B, and Sb.

The gate 320 is formed of polysilicon or a stack of polysilicon and tungsten silicide. A gate formed of a stack of polysilicon and tungsten silicide is used in this embodiment.

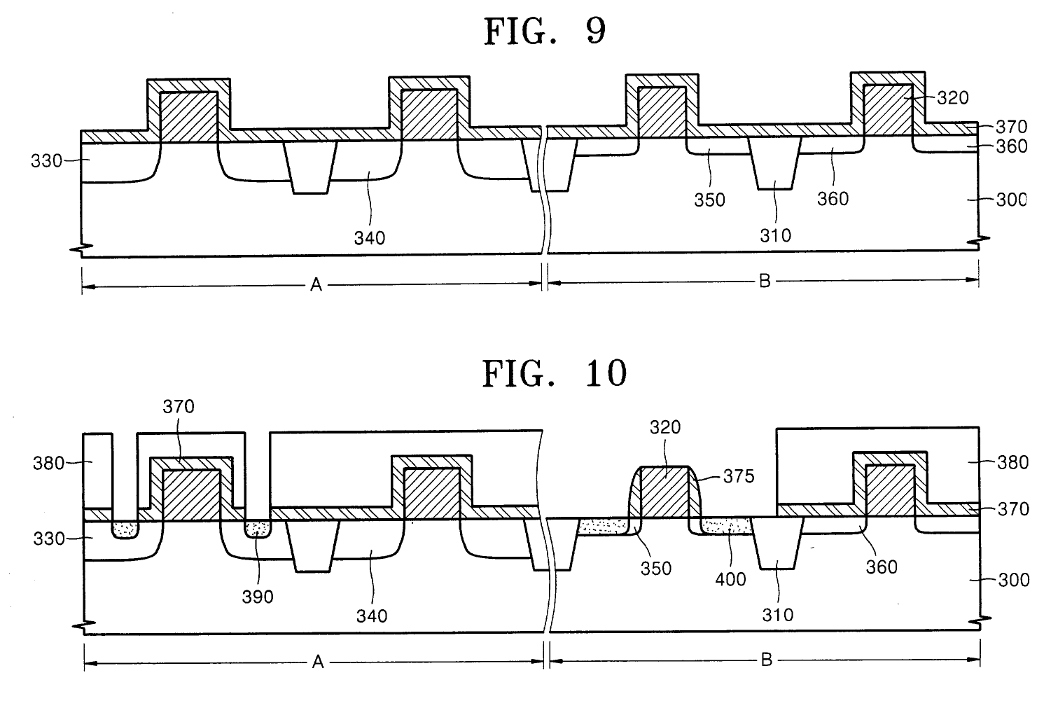

In FIG. 9, a spacer material layer 370 is formed on the entire surface of the semiconductor substrate 300 including the gate 320. In one embodiment, the spacer material layer 370 is formed of oxide and nitride.

In FIG. 10, a first photoresist pattern 380 is formed on the spacer material layer 370. The first photoresist pattern 380 exposes the spacer material layer 370 on the top surface of part of the low-concentration source and drain region 330 in the high-voltage NMOS region and the spacer material layer 370 in the low-voltage NMOS region.

The spacer material layer 370 on the top surface of part of the source and drain region 330 having a low impurity concentration in the high-voltage NMOS region and the spacer material layer 370 in the low-voltage NMOS region are etched using the first photoresist pattern 380 as a mask. As a result, a spacer 375 is formed on both sidewalls of the gate 320 in the low-voltage NMOS region. N-type ions having a high concentration of impurities are implanted into the semiconductor substrate 300 on which the spacer material layer 370 is etched, thereby forming a source and drain region 390 having a high impurity concentration in the high-voltage NMOS region and forming a source and drain region 400 having a high impurity concentration in the low-voltage NMOS region.

As shown in FIG. 10, source and drain regions in the high-voltage MOS region are formed of a double diffused drain (DDD) structure, in which the source and drain region 340 having a low impurity concentration surrounds the source and drain region 390 having a high impurity concentration. Source and drain regions in the low-voltage MOS region are formed of a lightly doped drain (LDD) structure.

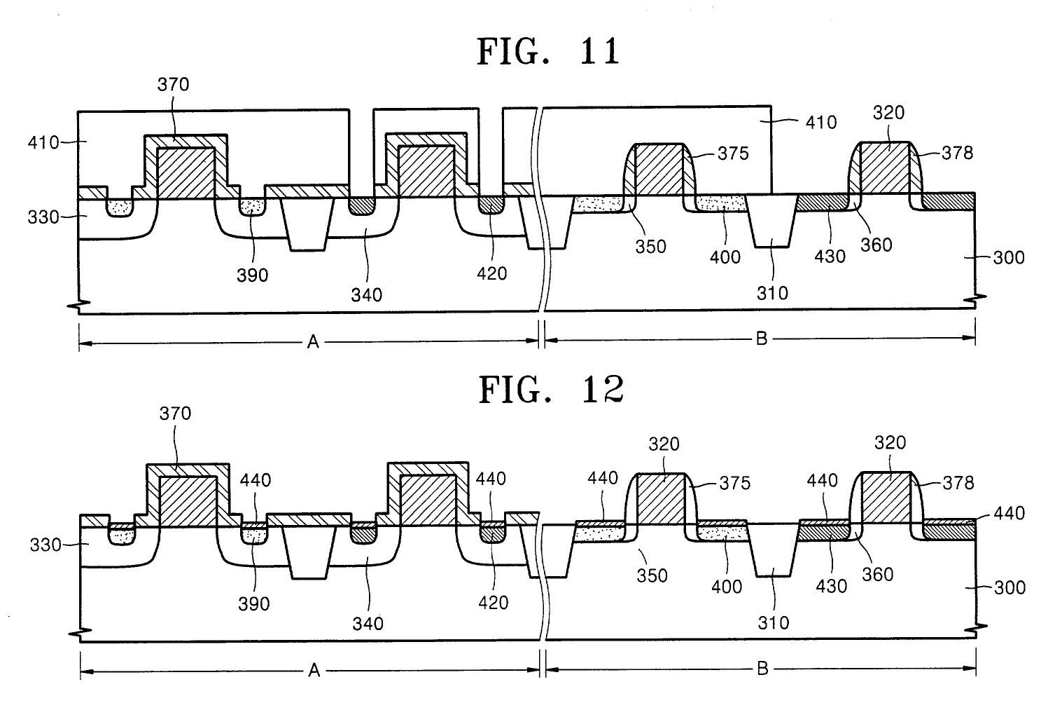

As shown in FIG. 11, the first photoresist pattern 380 is removed, and a second photoresist pattern 410 is formed on the semiconductor substrate 300. The second photoresist pattern 410 exposes the spacer material layer 370 on the top surface of part of the source and drain region 340 having a low impurity concentration in the high-voltage PMOS region and the spacer material layer 370 in the low-voltage PMOS region.

The spacer material layer 370 on the top surface of part of the source and drain region 340 having a low impurity concentration in the high-voltage PMOS region and the spacer material layer 370 in the low-voltage PMOS region are etched using the second photoresist pattern 410 as a mask. A spacer 378 is formed on both sidewalls of the gate 320 in the low-voltage PMOS region. P-type ions having a high concentration of impurities are implanted into the semiconductor substrate 300 on which the spacer material layer 370 is etched, thereby forming a source and drain region 420 having a high impurity concentration in the high-voltage PMOS region and forming a source and drain region 430 having a high impurity concentration in the low-voltage PMOS region. The spacer material layer 370 remains on the entire surface of the semiconductor substrate 300 exclusive of the source and drain region 420 having a high impurity concentration.

The second photoresist pattern 410 is removed, and a metal having a high melting point, such as Co, Ti, or Ni, is deposited on the entire surface of the semiconductor substrate 300, as shown in FIG. 12. A self-aligned silicide layer 440 is formed on the top surface of the source and drain regions 390, 420, 400, and 430, each having a high impurity concentration, in the high-voltage NMOS and PMOS regions and in the low-voltage NMOS and PMOS regions.

As described above, an extra silicide blocking layer (SBL) is not formed in this embodiment, and thus there is no need to perform a photomask process of patterning a SBL. That is, a photomask process can be reduced in comparison with a conventional process of selectively forming a silicide layer. Thus, a process of manufacturing a semiconductor device can be simplified, thereby reducing process costs. Owing to the reduction in the number of photomask processes, the possibility of misalignment can be reduced.

The silicide layer 440 is not formed on the top surface of the gate 320, which is formed of a stack of polysilicon and tungsten silicide in the low-voltage MOS region. In a case where the gate 320 is formed of polysilicon, the silicide layer 440 is also formed on the top surface of the gate 320 in the low-voltage MOS region.

Although a LDI process is described as an embodiment of the present invention, the present invention can be applied to any process of selectively forming a silicide layer, for example, a merged flash memory logic (MFL) process.

A photoresist pattern, which exposes a region in which a silicide layer is to be formed, that is, exposes only gate electrodes of a memory cell, gate electrodes of a logic device, and source and drain regions, is formed before forming a spacer of gate electrodes even in the case of a MFL process. The spacer material layer is etched using the photoresist pattern, thereby forming the spacer. The source and drain region having a high impurity concentration is formed, and the silicide layer is formed on the source and drain region having a high impurity concentration.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A semiconductor device comprising:
a semiconductor substrate on which a first region is defined;
a gate formed in the first region of the semiconductor substrate;
a source and drain region having a high impurity concentration formed apart from the gate in the semiconductor substrate at both sides of the gate;
a source and drain region having a low impurity concentration formed to surround the source and drain region having a high impurity concentration in the semiconductor substrate at both sides of the gate;
a silicide layer formed on the top surface of the source and drain region having a high impurity concentration; and
a spacer layer formed on the surface of the semiconductor substrate in the first region in which the gate is formed and exposing only the silicide layer.

2. The semiconductor device of claim 1, wherein the semiconductor substrate further comprises:
a second region;
a gate formed in the second region of the semiconductor substrate;
a spacer formed on both sidewalls of the gate in the second region;
a source and drain region having a low impurity concentration formed under the spacer of the semiconductor substrate;
a source and drain region having a high impurity concentration formed outside of the spacer of the semiconductor substrate; and
a silicide layer formed on the top surface of the source and drain region having a high impurity concentration in the second region.

3. The semiconductor device of claim 1, wherein the spacer layer and the spacer are formed of one of oxide and nitride.

4. The semiconductor device of claim 2, wherein the spacer layer and the spacer are formed of one of oxide and nitride.

5. The semiconductor device of claim 1, wherein the silicide layer is formed of one of NiSi, TiSi, and CoSi.

6. The semiconductor device of claim 2, wherein the suicide layer is formed of one of NiSi, TiSi, and CoSi.

7. A method of manufacturing a semiconductor device, the method comprising:
preparing a semiconductor substrate, which includes a first region and a second region;
forming a gate on the first and second regions of the semiconductor substrate;
forming a source and drain region having a low impurity concentration at both sides of the gate in the semiconductor substrate;
forming a spacer material layer on the surface of the semiconductor substrate on which the gate and the source and drain region having a low impurity concentration are formed;
forming a spacer on both sidewalls of the gate in the first region by etching the spacer material layer in the first region;
forming a source and drain region having a high impurity concentration at both sides of the spacer in the semiconductor substrate; and
forming a silicide layer on the top surface of the source and drain region having a high impurity concentration.

8. The method of claim 7, wherein the step of forming a spacer in the first region further comprises:
simultaneously etching a spacer material layer formed on the top surface of part of the source and drain region having a low impurity concentration in the second region, and exposing part of the source and drain region having a low impurity concentration in the second region;
forming a source and drain region having a high impurity concentration on the exposed part of the source and drain region having a low impurity concentration in the second region; and
forming a silicide layer on the top surface of the source and drain region having a high impurity concentration; wherein
the first region is a low-voltage MOS device, and the second region is a high-voltage MOS device.

9. The method of claim 8, wherein the source and drain region having a low impurity concentration in the second region is formed deeper than the source and drain region having a low impurity concentration in the first region in the step of forming a source and drain region having a low impurity concentration in the first and second regions of the semiconductor substrate.

10. The method of claim 8, wherein the conductivity type of the low-voltage MOS device is the same as that of the high-voltage MOS device.

11. The method of claim 8, wherein the conductivity type of the low-voltage MOS device is different from that of the high-voltage MOS device.

12. The method of 7, wherein the spacer material layer is formed of one of oxide and nitride.

13. The method of claim 8, wherein the spacer material layer is formed of one of oxide and nitride.

14. The method of claim 7, wherein the step of forming a silicide layer comprises:
forming a metal having a high melting point on the surface of the semiconductor substrate on which the spacer material layer remains;
performing thermal treatment of the metal having a high melting point; and
removing the unreacted metal on the semiconductor substrate.

15. The method of claim 8, wherein the step of forming a silicide layer comprises:
forming a metal having a high melting point on the surface of the semiconductor substrate on which the spacer material layer remains;
performing thermal treatment of the metal having a high melting point; and
removing the unreacted metal on the semiconductor substrate.

16. The method of claim 14, wherein the metal having a high melting point is one of Co, Ti and Ni.

17. The method of claim 15, wherein the metal having a high melting point is one of Co, Ti and Ni.

18. A method of manufacturing a semiconductor device, the method comprising:
preparing a semiconductor substrate, which includes a high-voltage PMOS region, a high-voltage NMOS region, a low-voltage PMOS region, and a low-voltage NMOS region;
forming a gate and a source and drain region having a low impurity concentration in each region of the semiconductor substrate;
forming a spacer material layer on the surface of the semiconductor substrate on which the gate and the source and drain region having a low impurity concentration are formed;
forming a first photoresist pattern on the semiconductor substrate on which the spacer material layer is formed;
etching the spacer material layer formed on the top surface of part of the source and drain region having a low impurity concentration in the high-voltage NMOS region, using the first photoresist pattern and simultaneously forming a spacer on both sidewalls of the gate in the low-voltage NMOS region;
removing the first photoresist pattern;
forming a source and drain region having a high impurity concentration in the high-voltage NMOS region and a source and drain region having a high impurity concentration in the low-voltage NMOS region;
forming a second photoresist pattern on the semiconductor substrate;
etching the spacer material layer formed on the top surface of part of the source and drain region having a low impurity concentration in the high-voltage PMOS region, using the second photoresist pattern and simultaneously forming a spacer on both sidewalls of the gate in the low-voltage PMOS region;
removing the second photoresist pattern;
forming a source and drain region having a high impurity concentration in the high-voltage PMOS region and a source and drain region having a high impurity concentration in the low-voltage PMOS region; and
forming a silicide layer on the top surface of the source and drain region having a high impurity concentration in the high-voltage PMOS and NMOS regions and on the top surface of the source and drain region having a high impurity concentration in the low-voltage PMOS and NMOS regions.

19. The method of claim 18, wherein the first photoresist pattern exposes the part of the source and drain region having a low impurity concentration in the high-voltage NMOS region and the low-voltage NMOS region, and the second photoresist pattern exposes the part of the source and drain region having a low impurity concentration in the high-voltage PMOS region and the low-voltage PMOS region.

20. The method of claim 18, wherein the spacer material layer is formed of one of oxide and nitride.

21. The method of claim 18, wherein the step of forming a silicide layer comprises:
forming a metal having a high melting point on the surface of the semiconductor substrate on which the spacer material layer remains;
performing thermal treatment of the metal having a high melting point; and
removing the unreacted metal on the semiconductor substrate.

22. The method of claim 21, wherein the metal having a high melting point is one of Co, Ti and Ni.
